(19) United States
(12) Patent Application Publication
(10) Pub. No.: US 2019/0306980 A1
(43) Pub. Date: Oct. 3, 2019

(54) FLEXIBLE PRINTED CIRCUIT BOARD, LAMINATE, METHOD OF MANUFACTURING FLEXIBLE PRINTED CIRCUIT BOARD

(71) Applicant: SHARP KABUSHIKI KAISHA, Sakai City (JP)

(72) Inventors: TAKUMA WATANABE, Sakai City (JP); SHINJI TOMOKAWA, Sakai City (JP); TAKAFUMI MATSUDA, Sakai City (JP); AKIYOSHI TAKAOKA, Sakai City (JP)

(21) Appl. No.: 16/358,621

(22) Filed: Mar. 19, 2019

(30) Foreign Application Priority Data
Mar. 27, 2018 (JP) 2018-060593

(51) Int. Cl. H05K 1/14; H05K 1/02; H05K 3/36

(52) U.S. Cl. CPC H05K 1/147; H05K 1/0298; G02F 1/13452; H05K 2201/10136; H05K 3/361

(57) ABSTRACT

An embodiment of the present invention provides a flexible printed circuit board (1) which is distinguishable from another flexible printed circuit board by use of an identifier. The flexible printed circuit board (1) includes: a base layer (13); a wiring layer (14); a surface cover layer (15); and an identifier (121) which allows the flexible printed circuit board (1) to be distinguished from another flexible printed circuit board, the surface cover layer (15) being formed in a surface cover region (11) while not being formed in a non-surface cover region (12), and the identifier (121) being provided in the non-surface cover region (12).

This Nonprovisional application claims priority under U.S.C. § 119 on Patent Application No. 2018-060593 filed in Japan on Mar. 27, 2018, the entire contents of which are hereby incorporated by reference.

### TECHNICAL FIELD

The present invention relates to a flexible printed circuit board, a laminate, and a method of manufacturing a flexible printed circuit board.

### BACKGROUND ART

Recently, flexible printed circuit boards (also referred to as “flexible printed circuits” or “FPCs”), which are pliable and flexible, have become essential for electronic devices such as liquid crystal display devices. Some liquid crystal modules to be provided in liquid crystal display devices are designed such that a two-dimensional barcode or the like is printed, for identification, on individual components (e.g., a liquid crystal panel) of a liquid crystal module. In such a case, however, after the liquid crystal module is assembled, it is not possible to easily check the barcode or the like of the liquid crystal panel (to ensure easy traceability of the liquid crystal module) because a cover glass is bonded to the liquid crystal panel. One possible solution to such a problem is to print panel ID information in the form of a barcode on the surface of an FPC, which has been connected in the liquid crystal module, halfway through production of the liquid crystal module.

Note that Patent Literature 1 discloses a flexible printed circuit board 81 on which a recognition mark 84 is provided so as to improve positional detection accuracy, with a view to increasing precision of positional alignment between an FPC and a liquid crystal panel which are to be bonded to each other by thermal compression.

### CITATION LIST

### Patent Literature

[Patent Literature 1]

Japanese Patent Application Publication Tokukai No. 2002-268574 (Publication Date: Sep. 20, 2002)

### SUMMARY OF INVENTION

### Technical Problem

However, the above configuration has a problem that the top surface of the FPC is generally covered with, for example, a coverlay which reflects light and reflection of light due to the coverlay makes a barcode reader unable to read a barcode.

The present invention has been accomplished in view of the foregoing problem and an object of the present invention is to provide a technique for making it easy to read an identifier which allows a flexible printed circuit board to be distinguished from another flexible printed circuit board.

### Solution to Problem

In order to solve the above problem, a flexible printed circuit board in accordance with an aspect of the present invention includes: a base layer; a wiring layer; a surface cover layer; and an identifier which allows the flexible printed circuit board to be distinguished from another flexible printed circuit board, the surface cover layer being formed in a surface cover region while not being formed in a non-surface cover region, and the identifier being provided in the non-surface cover region.

### Advantageous Effects of Invention

An aspect of the present invention makes it easy to read an identifier which allows a flexible printed circuit board to be distinguished from another flexible printed circuit board.

### BRIEF DESCRIPTION OF DRAWINGS

FIG. 1 illustrates a configuration in which a flexible printed circuit board in accordance with Embodiment 1 of the present invention is mounted to a liquid crystal module.

FIG. 2 is a cross-sectional view taken along line A-A of FIG. 1.

FIG. 3 illustrates a configuration in which a flexible printed circuit board in accordance with Embodiment 2 of the present invention is mounted to a liquid crystal module.

FIG. 4 illustrates a configuration of a flexible printed circuit board in accordance with Embodiment 3 of the present invention.

FIG. 5 is a flowchart showing a method of manufacturing a flexible printed circuit board in accordance with an embodiment of the present invention.

### DESCRIPTION OF EMBODIMENTS

### Embodiment 1

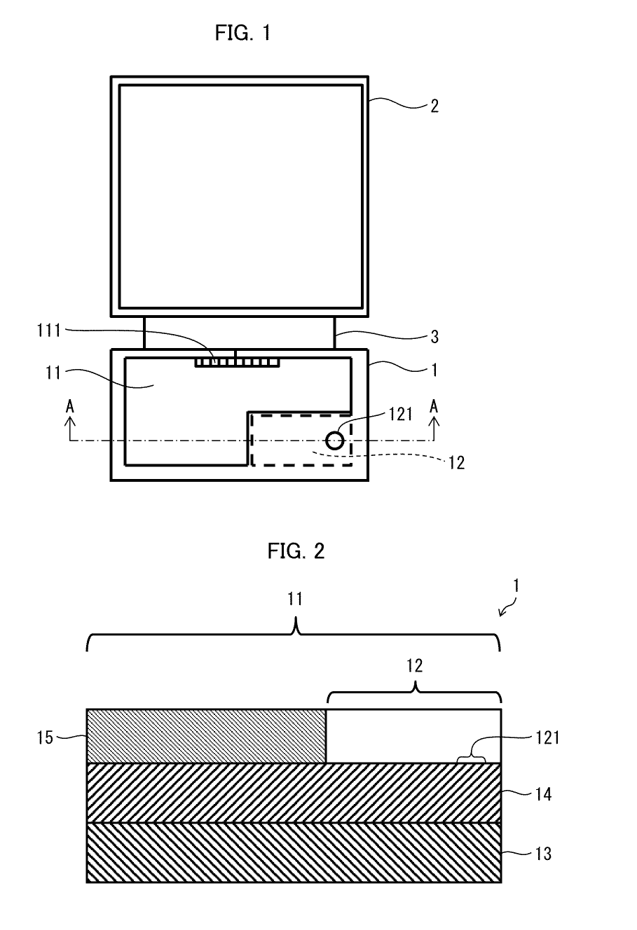

The following description will discuss Embodiment 1 of the present invention, with reference to FIGS. 1 and 2. Note that Embodiment 1 describes, as an example, a configuration in which a flexible printed circuit board (hereinafter also referred to as an “FPC”) 1 for driving a liquid crystal panel has a sufficient space for provision of an identifier 121 such as a barcode. Illustration of other constituent members is accordingly omitted in drawings.

(Overall Configuration)

The following description will discuss, with reference to FIGS. 1 and 2, an overall configuration in which the FPC 1 of Embodiment 1 is mounted to a liquid crystal module 2. FIG. 1 illustrates a configuration in which the FPC 1 is mounted to the liquid crystal module 2. FIG. 2 is a cross-sectional view taken along line A-A of FIG. 1.

The FPC 1 is mounted to the liquid crystal module 2, for example, via a connecting section 3 (see FIG. 1). The FPC 1 is a laminate of a base layer 13, a wiring layer 14, and a surface cover layer 15. Further, the FPC 1 is provided with (i) a surface cover region 11 in which the surface cover layer 15 is formed and (ii) a non-surface cover region 12 in which the surface cover layer 15 is not formed. The identifier 121 is provided in the non-surface cover region 12. The identifier 121 allows the FPC 1 to be distinguished from another FPC. This configuration is illustrated in FIGS. 1 and 2.

In FIG. 1, the reference sign 111 denotes a connector via which the FPC 1 is connected with the connecting section 3.

The surface cover layer 15 constitutes the top surface of the FPC 1 and is generally formed of a glossy insulating material. In Embodiment 1, the surface cover layer 15 constitutes a layer of the surface cover region 11, while the non-surface cover region 12 does not include the surface cover layer 15.

Examples of the identifier 121 include a barcode and a QR code (registered trademark). In a case where the identifier 121 is, for example, a barcode or a QR code, the barcode or the QR code can be provided, for example, by printing the barcode or the QR code. However, a type of the identifier 121 and how to provide the identifier 121 are not limited to the above ones. Any type of the identifier 121 and any way of providing the identifier 121 can be selected as appropriate as long as the identifier 121 allows an FPC, which includes the identifier 121, to be distinguished from another FPC.

With the above configuration, the identifier 121, which allows the FPC 1 to be distinguished from another FPC, is provided in the non-surface cover region 12. Thus, it is easy to read the identifier 121. This makes it possible to reliably identify the identifier during an actual manufacturing process and consequently, to ensure easy traceability of the FPC 1 during a manufacturing process or in a finished product.

(Surface Cover Layer)

In Embodiment 1, the surface cover layer 15 can include a coverlay layer. In design of FPCs, a coverlay, which generally constitutes the top surface of an FPC, is made of a glossy insulating material and thus, irregular reflection of light occurs at the coverlay when a barcode reader is used. This leads to a problem that the barcode reader cannot read a barcode or takes a long time to read a barcode.

In Embodiment 1, since the identifier 121 is provided in the non-surface cover region 12 in which the coverlay layer is not formed, it is easy to read the identifier 121. This makes it possible to more reliably identify the identifier 121 and consequently, to ensure easier traceability of the FPC 1 during a manufacturing process or a finished product.

(Wiring Layer)

In an example of Embodiment 1, the wiring layer 14 can include a wiring for transmitting display data. In this case, display data externally inputted is transmitted to the liquid crystal module 2 via the wiring layer 14 in a configuration in which the FPC 1 is mounted to the liquid crystal module 2.

In another example of Embodiment 1, the wiring layer 14 can include, for example, a wiring for transmitting a touch panel signal. In this case, an electric signal corresponding to a user's operation of touching a touch panel is transmitted to a control device (not illustrated) via the wiring layer 14.

In still another example of Embodiment 1, the wiring layer 14 can include a wiring for transmitting a backlight signal. In this case, a backlight signal, which is outputted from a backlight control device (not illustrated), is transmitted to a backlight device (not illustrated) via the wiring layer 14 in a configuration in which the FPC 1 is mounted to the liquid crystal module 2.

Though the above description has discussed, as an example, the configuration in which the wiring layer 14 includes the wiring for transmitting display data, a touch panel signal, or a backlight signal, Embodiment 1 is not limited to the configuration. The wiring layer 14 can include any other wiring as appropriate.

(Method of Manufacturing FPC)

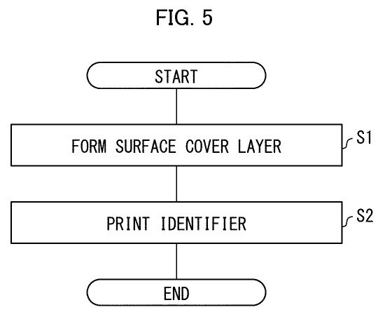

The following description will discuss, with reference to FIG. 5, a method of manufacturing the FPC of Embodiment 1. FIG. 5 is a flowchart illustrating the method of manufacturing the FPC of Embodiment 1. As illustrated in FIG. 5, the method of manufacturing the FPC 1 includes the steps of: forming the surface cover layer 15 in a region excluding the non-surface cover region 12 (step S1); and printing, in the non-surface cover region 12, the identifier 121 which allows the FPC 1 to be distinguished from another FPC (step S2).

Through the above steps, it is possible to manufacture the FPC 1 of Embodiment 1, which includes the base layer 13, the wiring layer 14, and the surface cover layer 15.

(Laminate)

The above description has discussed a case in which the configuration of Embodiment 1 is applied to an FPC. However, the configuration of Embodiment 1 is applicable to a laminate other than that of an FPC. In this case, the laminate includes a base layer, a wiring layer, and a surface cover layer. Further, the laminate is provided with (i) a surface cover region in which the surface cover layer is formed and (ii) a non-surface cover region in which the surface cover layer is not formed. The non-surface cover region is provided with an identifier which allows the laminate to be distinguished from another laminate. The configuration of the laminate is similar to that of the FPC 1 described with referenced to FIGS. 1 and 2.

With this configuration, the laminate can bring about the same effect as that of the FPC 1.

### Embodiment 2

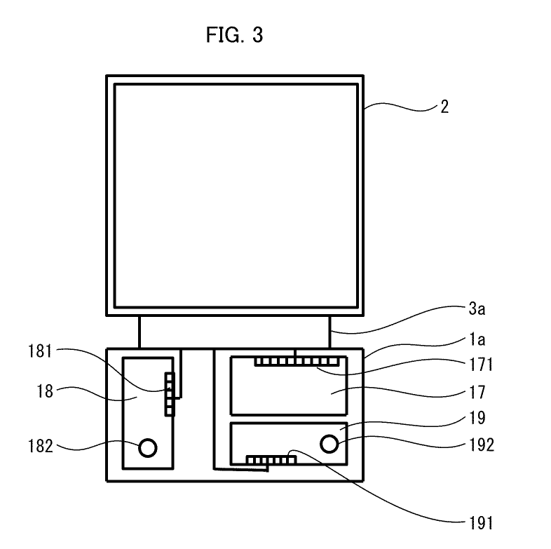

The following description will discuss, with reference to FIG. 3, Embodiment 2 of the present invention. Embodiment 2 differs from Embodiment 1 in that an FPC 1a is made up of a plurality of FPCs which are joined to each other or detached from each other. For convenience, members common to Embodiment 2 and Embodiment 1 are given the same reference signs and their detailed descriptions will be omitted here unless particularly necessary.

FIG. 3 illustrates a configuration in which the FPC 1a of Embodiment 2 is mounted to a liquid crystal module 2. Note that Embodiment 2 describes, as an example, a configuration in which an FPC 17 for driving a liquid crystal panel does not have a space for provision of an identifier (see FIG. 3).

In FIG. 3, the reference sign 18 denotes an FPC for driving a backlight; the reference sign 19 denotes an FPC for driving a touch panel; the reference signs 181 and 191 each denote a connector via which a corresponding FPC is connected with a connecting section 3a; and the reference sign 171 denotes a connector via which the FPC 17 is connected with the connecting section 3a.

The FPC 1a includes the FPC 17 for driving a liquid crystal panel, the FPC 18 for driving a backlight, and the FPC 19 for driving a touch panel, and the FPC 1a is mounted to the liquid crystal module 2, for example, via the connecting section 3a.

In Embodiment 2, the FPC 17 is entirely covered with a surface cover layer similar to that of the FPC 1 of Embodiment 1, while at least either the FPC 18 or the FPC 19 is provided with a non-surface cover region in which the surface cover layer is not formed.

As illustrated in FIG. 3, at least either the FPC 18 or the FPC 19 is provided, in the non-surface cover region, with an identifier (denoted by the reference sign 182 or 192 in FIG. 3), which allows the FPC 18 or the FPC 19 to be distinguished from another FPC.

An FPC may not always have a space enough to print an identifier on the surface of the FPC, due to a size reduction of the FPC or an increase in number of components to be mounted on the FPC, or the like. Under such circumstances, Embodiment 2 employs a configuration in which the FPC 19 or the FPC 18 has, at its surface, a non-surface cover region in which an identifier is provided. With this configuration, it is easy to read the identifier which allows the FPC 1a to be distinguished from another FPC.

In other words, Embodiment 2, which employs the above configuration, can bring about the same effect as that of Embodiment 1.

### Embodiment 3

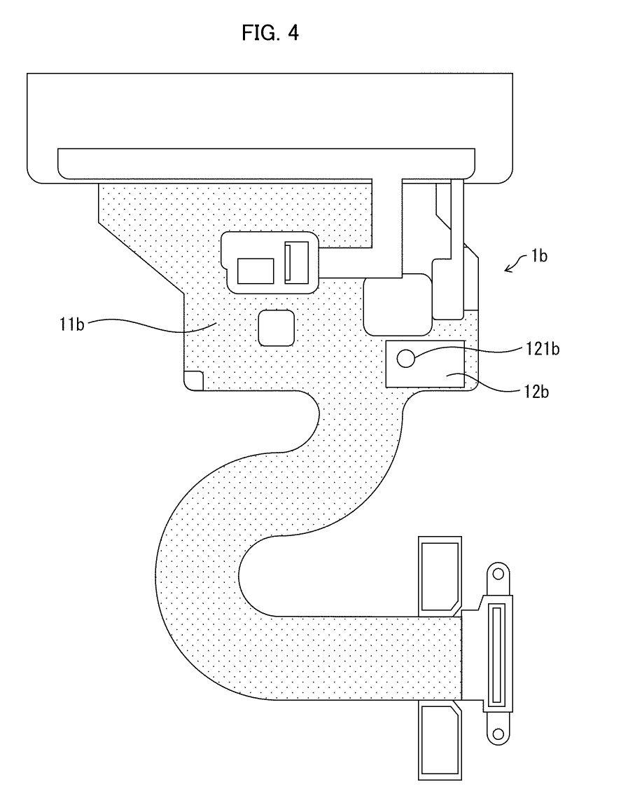

The following description will discuss, with reference to FIG. 4, Embodiment 3 of the present invention. For convenience, members common to Embodiment 3 and Embodiments 1 and 2 are given the same reference signs and their detailed descriptions will be omitted here unless particularly necessary.

FIG. 4 illustrates a configuration of an FPC 1b of Embodiment 3. In Embodiment 3, the FPC 1b is provided with (i) a region 11b which is entirely covered with a surface cover layer similar to that of Embodiment 1, and (ii) a region 12b which serves as a non-surface cover region in which the surface cover layer is not formed.

Embodiment 3 can employ a shielded FPC which includes an electromagnetic-wave shielding layer. The shielded FPC refers to an FPC having a shield structure which allows for high-speed transmission of a radio-frequency signal and for noise reduction. The shielded FPC can be prepared, for example, by forming an electromagnetic-wave shielding layer by printing with silver (Ag) paste.

In Embodiment 3, the surface cover layer can include an electromagnetic-wave shielding layer. In design of some FPCs, an electromagnetic-wave shielding layer is formed in an FPC so as to allow the FPC to have an improved performance.

Specifically, the FPC 1b illustrated in FIG. 4 includes, in the surface cover layer, an Ag layer which serves as the electromagnetic-wave shielding layer. If the identifier 121b were provided in the region 11b covered with the surface cover layer and, for example, the region 11b appeared black and glossy, the identifier 121b would be difficult to read in some cases.

In light of the above, Embodiment 3 employs a configuration in which the FPC 1b is provided with the non-surface cover region 12b in which the surface cover layer is not formed, and the identifier 121b is provided in the non-surface cover region 12b. This configuration makes it easy to read the identifier 121b which allows the FPC 1b to be distinguished from another FPC. In other words, according to the configuration of Embodiment 3, the identifier is provided in the non-surface cover region in which the electromagnetic-wave shielding layer is not formed, so that it is easy to read the identifier.

In addition, Embodiment 3 employs a configuration in which the electromagnetic-wave shielding layer is formed within the surface cover layer. This prevents the electromagnetic-wave shielding layer from becoming an obstacle to wirings provided in the FPC, and makes it possible to reliably shield the FPC from harmful electromagnetic waves.

The configuration of Embodiment 3 also brings about the same effect as those of Embodiments 1 and 2.

[Recap]

A flexible printed circuit board (1) in accordance with a first aspect of the present invention includes: a base layer (13); a wiring layer (14); a surface cover layer (15); and an identifier (121) which allows the flexible printed circuit board (1) to be distinguished from another flexible printed circuit board, the surface cover layer (15) being formed in a surface cover region (11) while not being formed in a non-surface cover region (12), and the identifier (121) being provided in the non-surface cover region (12).

This configuration allows the flexible printed circuit board to be distinguished from another flexible printed circuit board by use of the identifier. This makes it possible to ensure easy traceability of the flexible printed circuit board during a manufacturing process or in a finished product since the identifier can be reliably identified during an actual manufacturing process.

A flexible printed circuit board (1) in accordance with a second aspect of the present invention may be configured such that in the first aspect, the surface cover layer (15) includes a coverlay layer.

In this configuration, the non-surface cover region (12) includes no coverlay layer. This makes it possible to more reliably identify the identifier (121), and consequently, to ensure easier traceability of the flexible printed circuit board (1) during a manufacturing process or in a finished product.

A flexible printed circuit board (1) in accordance with a third aspect of the present invention may be configured such that in the first aspect, the surface cover layer (15) includes an electromagnetic-wave shielding layer.

This configuration makes it possible to reliably shield the flexible printed circuit board from harmful electromagnetic waves.

A flexible printed circuit board (1) in accordance with a fourth aspect of the present invention may be configured such that in any one of the first through third aspects, the wiring layer includes a wiring for transmitting display data.

A flexible printed circuit board (1) in accordance with a fifth aspect of the present invention may be configured such that in any one of the first through third aspects, the wiring layer includes a wiring for transmitting a touch panel signal.

A flexible printed circuit board (1) in accordance with a sixth aspect of the present invention may be configured such that in any one of the first through third aspects, the wiring layer includes a wiring for transmitting a backlight signal.

A laminate in accordance with a seventh aspect of the present invention includes: a base layer; a wiring layer; a surface cover layer; and an identifier which allows the laminate to be distinguished from another laminate, the surface cover layer being formed in a surface cover region while not being formed in a non-surface cover region, and the identifier being provided in the non-surface cover region.

This configuration can bring about the same effect as that of the first aspect.

A method in accordance with an eighth aspect of the present invention is a method of manufacturing a flexible printed circuit board which includes: a base layer; a wiring layer; a surface cover layer; and an identifier which allows the flexible printed circuit board to be distinguished from another flexible printed circuit board, the method including the steps of: forming the surface cover layer in a region excluding a non-surface cover region (step S1); and printing the identifier in the non-surface cover region (step S2).

This configuration makes it possible to manufacture a flexible printed circuit board which is distinguishable from another flexible printed circuit by use of an identifier.

The present invention is not limited to the foregoing embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### REFERENCE SIGNS LIST

1, 1a, 1b Flexible printed circuit board (FPC)
11, 11b Surface cover region
111 Connector
12, 12b Non-surface cover region
121, 121b Identifier
13 Base layer
14 Wiring layer
15 Surface cover layer
17 Flexible printed circuit board (for driving a liquid crystal panel)
18 Flexible printed circuit board (for driving a backlight)
19 Flexible printed circuit board (for driving a touch panel)
171, 181, 191 Connector
182, 192 Identifier
2 Liquid crystal module
3, 3a Connecting section

1. A flexible printed circuit board comprising:
a base layer;
a wiring layer;
a surface cover layer; and
an identifier which allows the flexible printed circuit board to be distinguished from another flexible printed circuit board,
the surface cover layer being formed in a surface cover region while not being formed in a non-surface cover region, and
the identifier being provided in the non-surface cover region.

2. The flexible printed circuit board as set forth in claim 1, wherein the surface cover layer includes a coverlay layer.

3. The flexible printed circuit board as set forth in claim 1, wherein the surface cover layer includes an electromagnetic-wave shielding layer.

4. The flexible printed circuit board as set forth in claim 1, wherein the wiring layer includes a wiring for transmitting display data.

5. The flexible printed circuit board as set forth in claim 1, wherein the wiring layer includes a wiring for transmitting a touch panel signal.

6. The flexible printed circuit board as set forth in claim 1, wherein the wiring layer includes a wiring for transmitting a backlight signal.

7. A laminate comprising:
a base layer;
a wiring layer;
a surface cover layer; and
an identifier which allows the laminate to be distinguished from another laminate,
the surface cover layer being formed in a surface cover region while not being formed in a non-surface cover region, and
the identifier being provided in the non-surface cover region.

8. A method of manufacturing a flexible printed circuit board which comprises:
a base layer;
a wiring layer;
a surface cover layer; and
an identifier which allows the flexible printed circuit board to be distinguished from another flexible printed circuit board,
said method comprising the steps of:
forming the surface cover layer in a region excluding a non-surface cover region; and
printing the identifier in the non-surface cover region.
